(19) United States
(12) Patent Application Publication
(10) Pub. No.: US 2022/0258429 A1
(43) Pub. Date: Aug. 18, 2022

(54) METHOD FOR JOINING A THERMOPLASTIC FILM TO A METAL COMPONENT

(71) Applicant: Hella GmbH & Co. KGaA, Lippstadt (DE)

(72) Inventors: Frank BRINKMEIER, Lippstadt (DE); Michael LAKENBRINK, Oelde (DE); Thomas WIESE, Lippstadt (DE)

(73) Assignee: Hella GmbH & Co. KGaA, Lippstadt (DE)

(21) Appl. No.: 17/735,200

(22) Filed: May 3, 2022

Related U.S. Application Data
(63) Continuation of application No. PCT/EP2020/080410, filed on Oct. 29, 2020.

(30) Foreign Application Priority Data
Nov. 4, 2019 (DE) 10 2019 129 591.2

(51) Int. Cl. B29C 65/16; B29C 65/00; F21S 45/47

(52) U.S. Cl. CPC B29C 65/16; B29C 66/742; F21S 45/47; B29C 66/72; B29C 66/7392

(57) ABSTRACT

A method for joining a thermoplastic film to a metal component, at least comprising the following method steps: providing the metal component with a joining surface, incorporating microstructures and/or nanostructures into the joining surface of the metal component, arranging the thermoplastic film on the joining surface of the metal component, softening the thermoplastic film by heating to a temperature above the glass transition temperature of the thermoplastic film, pressing the softened thermoplastic film onto the joining surface of the metal component in such a way that part of the softened thermoplastic film penetrates into the microstructures and/or nanostructures in the joining surface of the metal component, and obtaining an interlocking connection between the thermoplastic film and the metal component after the thermoplastic film has cooled.

This nonprovisional application is a continuation of International Application No. PCT/EP2020/080410, which was filed on Oct. 29, 2020, and which claims priority to German Patent Application No. 10 2019 129 591.2, which was filed in Germany on Nov. 4, 2019, and which are both herein incorporated by reference.

### BACKGROUND OF THE INVENTION

### Field of the Invention

The present invention relates to a method for joining a thermoplastic film to a metal component.

### Description of the Background Art

Joint connections between films, made of thermoplastics, and metal components are found, for example, in light modules of vehicle lighting devices. There, thermoplastic films are used as so-called circuit carrier films, on the upper side of which metal trace structures have been printed, vapor-deposited, or galvanically deposited. These traces are used for electrical contacting, in particular of an illuminant, and can be used both for providing the necessary supply voltage and for transmitting control signals. The bottom side of the circuit carrier film is connected in a planar manner to a metal heat sink, which is used to dissipate the waste heat, generated during operation of the light module, from the illuminant and supply lines.

In light modules according to the prior art, the circuit carrier film is usually bonded to the surface of the heat sink by means of an adhesive. Such a joining method has process-related disadvantages and also leads to a limitation of the functionality of the joint connection with regard to heat dissipation. Thus, the use of an adhesive, especially a liquid adhesive, must always be regarded as a potential starting point for contamination of the overall process, and in addition, the adhesive and the associated application technology also represent a cost factor. In terms of the functionality of the assembly, a detrimental effect of the adhesive layer is that it creates additional thermal resistance between the thermoplastic film and the heat sink, which undesirably lowers the thermal conductivity value of the assembly.

US 2005/0079373 A1 discloses a method for the adhesive-free joining of a plastic component with a component made of another material, for example, a metal, which is based on activating the joining surface of the plastic component by means of high-energy irradiation and thus enabling the formation of a chemical bond with the other component. A disadvantage of this method is that it must be carried out under clean room conditions in order to prevent contamination and thus saturation of the activated joining surface.

U.S. Pat. No. 4,022,648 A discloses a method for the adhesive-free joining of a thermoplastic component to a substrate, for example, a metallic substrate, for which a combination of heating the thermoplastic component in an arrangement on the substrate and simultaneously applying an electrical potential difference between the component and the substrate is proposed.

The subsequently published DE 10 2019 106 260.8, which corresponds to US 2021/0402712, which is incorporated herein by reference, discloses a method for producing a joint connection in a lighting device of a vehicle between a metal component and a luminously efficacious plastic component, in particular a reflector, a light-conducting body, a thick-walled optical element, or a primary optical element, wherein the joining surface of the metal component has a microstructure with undercuts, and wherein the plastic component is thermally softened and pressed into the microstructure so that, after cooling and solidification of the plastic component, there is a bond with the metal component.

### SUMMARY OF THE INVENTION

It is therefore an object of the present invention to provide a method for joining a thermoplastic film to a metal component, which is particularly suitable for joining a circuit carrier film to a heat sink as components of a light module.

In an exemplary embodiment of the invention, a method is proposed that comprises: providing the metal component with a joining surface; incorporating microstructures and/or nanostructures into the joining surface of the metal component; arranging the thermoplastic film on the joining surface of the metal component; softening the thermoplastic film by heating to a temperature above the glass transition temperature of the thermoplastic film; pressing the softened thermoplastic film onto the joining surface of the metal component in such a way that part of the softened thermoplastic film penetrates into the microstructures and/or nanostructures in the joining surface of the metal component; and obtaining an interlocking connection between the thermoplastic film and the metal component after the thermoplastic film has cooled.

The invention is based on the idea of using the softening of the thermoplastic material with a heat supply to press part of the film into a suitably dimensioned surface structure on the joining surface of the metal component, so that after cooling and solidification, the film is in the state of positive interlocking with the surface structure. Thermoplastics are amorphous or semi-crystalline plastics whose essential structural element consists of sparsely branched or unbranched carbon chains. They are characterized by a thermoplastic physical state in which the material is soft and no longer dimensionally stable. The transition to this thermoplastic state takes place when a material-specific glass transition temperature is exceeded, below which the thermoplastic is in a solid or thermoelastic state. In the thermoplastic system, the material is not yet flowable, so that when the method of the invention is carried out, the underside of the thermoplastic film can be pressed into the metal surface structure while the structural integrity of the upper side of the film is maintained. With regard to the use of the film as a circuit carrier, this means that traces or other MEMS components deposited on the upper side of the film are not affected by the joining process. Suitable materials for thermoplastic films are, for example, acrylonitrile butadiene styrene (ABS), polyamides (PA), polylactate (PLA), polymethyl methacrylate (PMMA), polycarbonate (PC), polyethylene terephthalate (PET), polyethylene (PE), polypropylene (PP), polystyrene (PS), polyether ether ketone (PEEK), or polyvinyl chloride (PVC).

The microstructures and/or nanostructures incorporated into the joining surface of the metal component can, for example, have the form of groove-like depressions in a rectilinear or meandering shape or have a more complex topography, for example, a combination of cavities and surface elevations. The dimensions of the surface structures in this case are preferably adapted to the deformability of the specific thermoplastic material of the film. In particular, nanostructuring can provide for a specific change in surface energy and thereby influence the degree of wetting of the metal surface with the softened thermoplastic.

Thus, despite the advantage of not using an adhesive, the joining method of the invention can be used to create a bond between a thermoplastic film and a metal component that is sufficiently strong and durable for many applications, in particular for joining a circuit carrier film to a heat sink as components of a light module. In addition, the micro- and/or nanostructuring of the joining surface increase the effective interface between the film and the metal body, so that a particularly rapid heat dissipation from the film into the metal body is made possible.

Undercuts can be introduced into the joining surface of the metal component during the incorporation of the microstructures and/or nanostructures. Geometric undercuts can be enclosed by the softened thermoplastic material so that, after solidification of the thermoplastic, an interlocking connection is formed along the plane normal direction of the joining surface. Such undercuts can be in the form of steps or bulges in a cavity, for example.

Preferably, the incorporation of the microstructures and/or nanostructures into the joining surface of the metal component can be carried out by means of an electrochemical process or by means of a laser material processing method or by means of a mechanical process. For example, electrochemical ablation processes are suitable for introducing complex surface structures into metallically conductive workpieces with accuracies in the micrometer range. For greater manufacturing precision down to the nanometer range, modern methods of laser material processing and photonics can be used. Mechanical processes are cost-effective alternatives, wherein, for example, structures with undercuts can also be realized by means of a combination of milling and hammering.

The heating of the thermoplastic film can be carried out by means of laser irradiation or by means of infrared irradiation or by means of a convective heat supply or by means of inductive or contact heating of the metal component. The use of a laser source offers in particular the advantage of controlled local heating, for example, in order to build up a joint connection only in sections. In this case, the laser radiation can be absorbed either directly by the thermoplastic film or by the metal joining partner located underneath, so that the film is advantageously heated indirectly in the area of its underside facing the joining surface of the metal body, whereas the upper side of the film, on which traces or other electronic components can be accommodated, is less thermally stressed. This is also achieved by inductive or contact heating of the metal component. The convective heat supply can be generated, for example, by means of hot air guns directed at the thermoplastic film and/or the metal component.

Preferably, the heated thermoplastic film can be pressed onto the joining surface of the metal component by means of negative pressure and/or by means of mechanical pressure. For example, the metal component is accommodated in a mask, for instance, a film thermoforming machine, and the thermoplastic film is placed on the mask so that when the mask is evacuated, the film is pressed onto the joining surface on the metal component. Alternatively or in addition, for example, a suitably shaped punch can be used to mechanically press on the film.

With further advantage, during and/or following the pressing of the heated thermoplastic film onto the joining surface of the metal component, the thermoplastic film and/or the metal component are actively cooled. The active cooling can be realized, for example, by means of a fan or by Peltier elements in contact with the metal component. Active cooling reduces the processing time of the method step and reduces the thermal load for any electronic elements located on the upper side of the film.

Furthermore, the invention relates to a method for joining a first thermoplastic film to a metal component and a second thermoplastic film to the first thermoplastic film, comprising at least the following method steps: joining the first film to the component by means of an embodiment of the aforementioned method, arranging the second film on the first film, softening the first film and the second film by heating to a temperature above the glass transition temperature of the films, pressing the softened second film onto the softened first film, and obtaining a bonded connection between the second film and the first film after the films have cooled.

This method thus represents an extension of the method of the invention in that a further thermoplastic film serves as a connecting element, which forms an interlocking connection on the underside with the structured joining surface of the metal component and is connected in a bonded manner to the second film which is arranged on the upper side and is designed in particular as a circuit carrier film. It is necessary in this case for both films to be made from the same thermoplastic or from two thermoplastics that are compatible in terms of their glass transition temperatures and mutual crosslinkability. This extended joining method is particularly advantageous when a circuit carrier film with especially sensitive electronic elements is used and potentially occurring local deformations of the film top surface must be avoided during pressing into the surface structure of the joining surface.

In addition, the invention relates to a light module for a motor vehicle lighting device at least comprising an illuminant, a metal heat sink, and a thermoplastic circuit carrier film, wherein the circuit carrier film has traces for making electrical contact with the illuminant, characterized in that the circuit carrier film is connected to the heat sink, wherein the connection is produced by means of an embodiment of the aforementioned joining methods.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1a shows a view of a heat sink as a component of a light module of the invention;

FIG. 1b shows a view of a light module of the invention;

FIG. 2 is a cross section of FIG. 1b; and

FIGS. 3a and 3b show connections of the invention as enlarged excerpts from FIG. 2.

### DETAILED DESCRIPTION

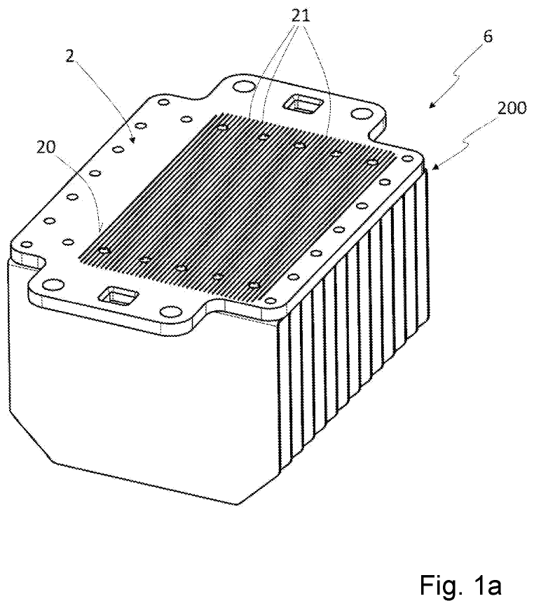

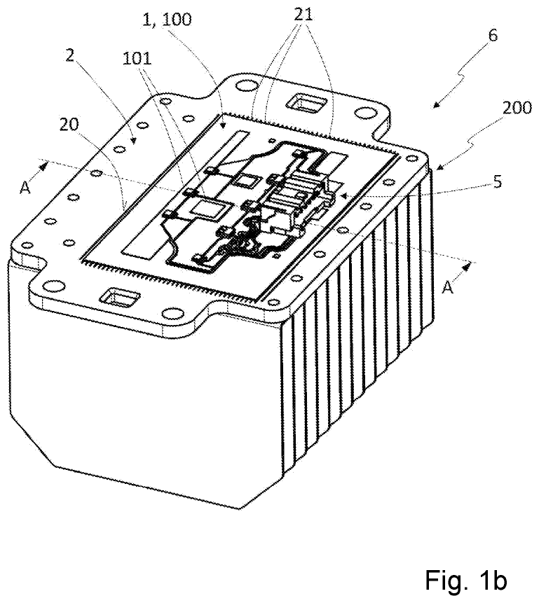

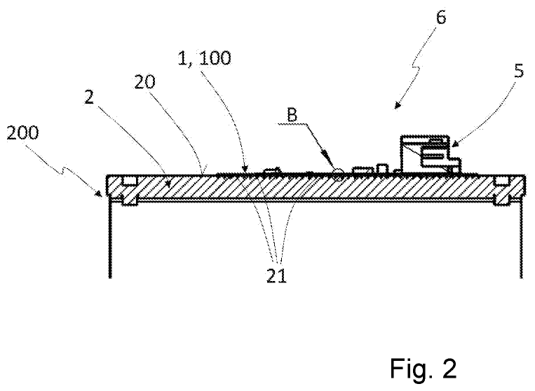

FIGS. 1a and 1b show perspective views of components of a light module 6 of the invention, and FIG. 2 shows a corresponding cross-sectional view along section line AA. The main components of light module 6 are heat sink 200 as a metal component 2, circuit carrier film 100 based on thermoplastic film 1, and illuminant 5, the latter being shown only in FIGS. 1b and 2.

Heat sink 200 is made of an aluminum, magnesium, or copper alloy, for example, and comprises a plurality of cooling fins and a plate disposed thereon for receiving illuminant 5 to be cooled. Joining surface 20 for connection to circuit carrier film 100 lies on this plate. Within the scope of the joining process of the invention, microstructures 21 running linearly parallel to one another have been incorporated into joining surface 20.

Circuit carrier film 100 has a plurality of metal traces 101 on its upper side for contacting illuminant 5 electrically connected thereto, wherein illuminant 5 comprises further electronic peripherals for control and/or sensors in addition to a light source.

Circuit carrier film 100 covers the joining surface (20) region provided with microstructures 21. It can be seen in the cross-sectional view of FIG. 2 that the microstructures represent groove-like depressions and, in the course of the joining method of the invention, are filled by part of thermoplastic film 1 which has been pressed in in the softened, thermoplastic state.

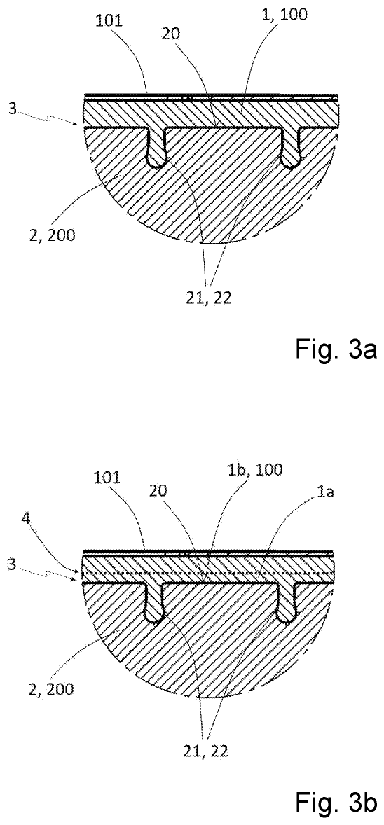

FIGS. 3a and 3b show enlarged detailed views of the image detail B of FIG. 2. wherein FIGS. 3a and 3b are to be understood as embodiments of the connection of circuit carrier film 100 to heat sink 200, said embodiments being alternatives with respect to one another.

Microstructures 21 incorporated into joining surface 20 of metal component 2 have a peg-shaped cross section with a dome-shaped widening at the end, as a result of which undercuts 22 are formed. The parts of thermoplastic film 1 or 1a that have penetrated microstructures 21 thus form an interlocking connection 3, in the horizontal and vertical directions, with metal component 2. Said connection 3 is temperature resistant until the glass transition temperature of the thermoplastic used is exceeded again.

In FIG. 3a, circuit carrier film 100 has been joined directly to heat sink 200 in an interlocking connection 3, whereas in the embodiment shown in FIG. 3b, thermoplastic film 1a as an additional joining element builds up interlocking connection 3, and in subsequent method steps, the bonded connection 4 with thermoplastic film 1b of circuit carrier film 100 has been produced. The latter variant serves to protect traces 101 or other components fixedly arranged on the upper side of circuit carrier film 100 from potential damage during the creation of interlocking connection 3.

The invention is not limited in its implementation to the preferred exemplary embodiment described above. Rather, a number of variants are conceivable which make use of the shown solution even in the case of fundamentally different embodiments. All features and/or advantages arising from the claims, the description, or the drawings, including structural details, spatial arrangements, and method steps, can be essential to the invention both individually and in a wide variety of combinations.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for joining a thermoplastic film to a metal component, the method comprising:
providing the metal component with a joining surface;
incorporating microstructures and/or nanostructures into the joining surface of the metal component;
arranging the thermoplastic film on the joining surface of the metal component;
softening the thermoplastic film by heating to a temperature above a glass transition temperature of the thermoplastic film;
pressing the softened thermoplastic film onto the joining surface of the metal component such that part of the softened thermoplastic film penetrates into the microstructures and/or nanostructures in the joining surface of the metal component; and
obtaining an interlocking connection between the thermoplastic film and the metal component after the thermoplastic film has cooled.

2. The method according to claim 1, wherein undercuts are introduced into the joining surface of the metal component during the incorporation of the microstructures and/or nanostructures.

3. The method according to claim 1, wherein the incorporation of the microstructures and/or nanostructures into the joining surface of the metal component is carried out by an electrochemical process or by a laser material processing method or by a mechanical process.

4. The method according to claim 1, wherein the heating of the thermoplastic film is carried out by laser irradiation or by infrared irradiation or by a convective heat supply or by inductive or contact heating of the metal component.

5. The method according to claim 1, wherein the heated thermoplastic film is pressed onto the joining surface of the metal component by negative pressure and/or by mechanical pressure.

6. The method according to claim 1, wherein during and/or following the pressing of the heated thermoplastic film onto the joining surface of the metal component, the thermoplastic film and/or the metal component are actively cooled.

7. A method for joining a first thermoplastic film to a metal component and a second thermoplastic film to the first thermoplastic film, the method comprising:
joining the first film to the component by the method according to claim 1;
arranging the second film on the first film;
softening the first film and the second film by heating to a temperature above a glass transition temperature of the first and second films;
pressing the softened second film onto the softened first film; and
obtaining a bonded connection between the second film and the first film after the films have cooled.

8. A light module for a motor vehicle lighting device, the light module comprising:
an illuminant;
a metal heat sink; and
a thermoplastic circuit carrier film,
wherein the circuit carrier film has traces for making electrical contact with the illuminant,
wherein the circuit carrier film is connected to the heat sink, and
wherein the connection is produced by the method according to claim 1.
